(19) United States
(12) Patent Application Publication
(10) Pub. No.: US 2006/0013411 A1
(43) Pub. Date: Jan. 19, 2006

(54) On a support seat of an audio player

(76) Inventor: Chung-Hung Lin, Syuejia Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/890,194

(22) Filed: Jul. 14, 2004

(51) Int. Cl. H04R 1/02; H05K 5/00

(52) U.S. Cl. 381/87; 381/305; 381/336; 381/386; 181/148

(57) ABSTRACT

A support seat of an audio player includes a main body, and various adjusting members; the main body has speakers at two ends thereof, and a holding room for an audio player to be fitted in; the adjusting members can be firmly held in the holding room of the main body, and they have different shapes and sizes so as to cause change to dimensions of the holding room in respective ways when they are fitted in position in the holding room; thus, music can be played through the speakers after an audio player is connected with the main body of the support seat, and audio players with different sizes can be held steady on the support seat with help of suitable ones of the adjusting members.

### BACKGROUND OF THE INVENTION

1. Field of the invention

The present invention relates to a support seat of an audio player, more particularly one, which includes a main body, and various adjusting members used for changing the dimensions of a holding room of the main body in respective ways, which room is provided for receiving an audio player therein; thus, audio players with various sizes can be held steady on the support seat with the help of suitable adjusting members.

2. Brief Description of the Prior Art

Many kinds of audio appliances and video appliances are available for people to choose, e.g. MP 3 players, and CD players.

MP 3 players are specially used for playing MP3 music. The complete name of MP 3 is MPEG (Movie Picture Experts group) 1 Layer 3. MP 3 players are usually used with headphones like a Walkman. And, a MP 3 player can be connected with, and held steady on a support seat equipped with speakers such that music can be played through the speakers of the support seat for many people to listen to; support seats of such types are usually formed with a holding cavity for a MP 3 player to be closely fitted in.

Because there are various specifications of MP 3 players, various support seats whose holding rooms have different sizes have to be provided for suiting all specifications of MP 3 players. Therefore, such support seats have very limited use, and will cause trouble to the manufacturers as well as inconvenience to the users.

### SUMMARY

It is a main object of the present invention to provide an improvement on a support seat of an audio player to overcome the above disadvantages.

The support seat of the present invention includes a main body, and various adjusting members. The main body has speakers at two ends thereof, and a holding room for an audio player to be fitted in. The adjusting members can be firmly held in the holding room of the main body, and they have different shapes and sizes so as to cause change to dimensions of the holding room in respective ways when they are fitted in the holding room. Thus, music can be played through the speakers after an audio player is connected with the main body of the support seat. And, audio players with different sizes can be held steady on the support seat with help of suitable ones of the adjusting members.

### BRIEF DESCRIPTION OF THE DRAWINGS

The present invention will be better understood by referring to the accompanying drawings, wherein:

FIG. 1 is an exploded perspective view of a first embodiment of a support seat of an audio player in the present invention,

FIG. 2 is a perspective view of the first embodiment, ready for use with an audio player,

FIG. 3 is a perspective view of the first embodiment, ready for use with another audio player, and

FIG. 4 is an exploded perspective view of a second embodiment of a support seat of an audio player in the present invention.

### DETAILED DESCRIPTION OF THE PREFERRED EMBODIMENTS

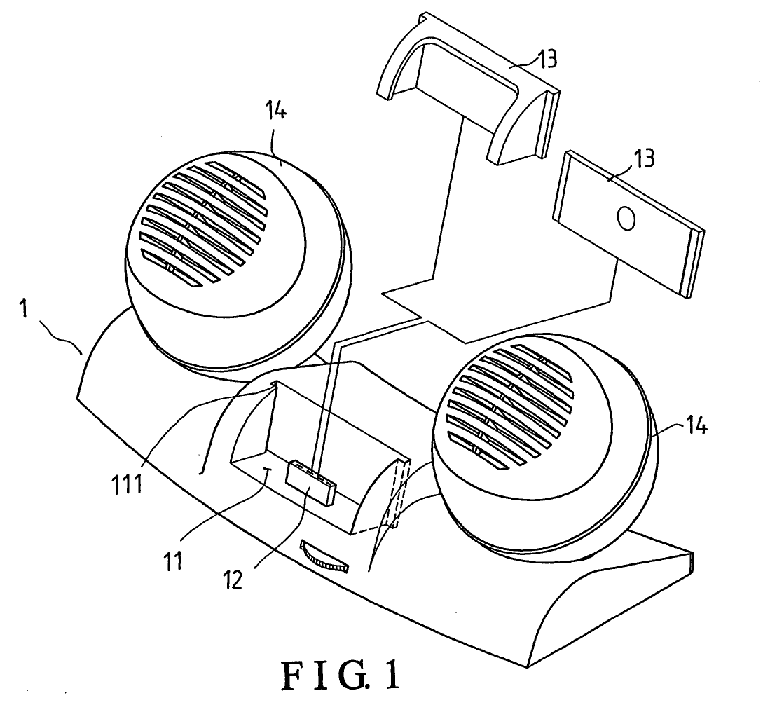

Referring to FIG. 1, a preferred embodiment of a support seat of an audio player includes a main body 1, and several adjusting members 13.

The main body 1 has speakers 14 at two ends thereof, and a holding portion 11 between the speakers 14 at a front. The holding portion 11 is formed with a holding room, and fitting trenches 111, which face and communicate with two sides of a rear end of the holding room. Furthermore, a connecting terminal 12 is disposed on the holding portion 11 in a vertical position. Thus, music can be played through the speakers 14 of the support seat 1 after an audio player is passed into the holding room, and connected with the terminal 13.

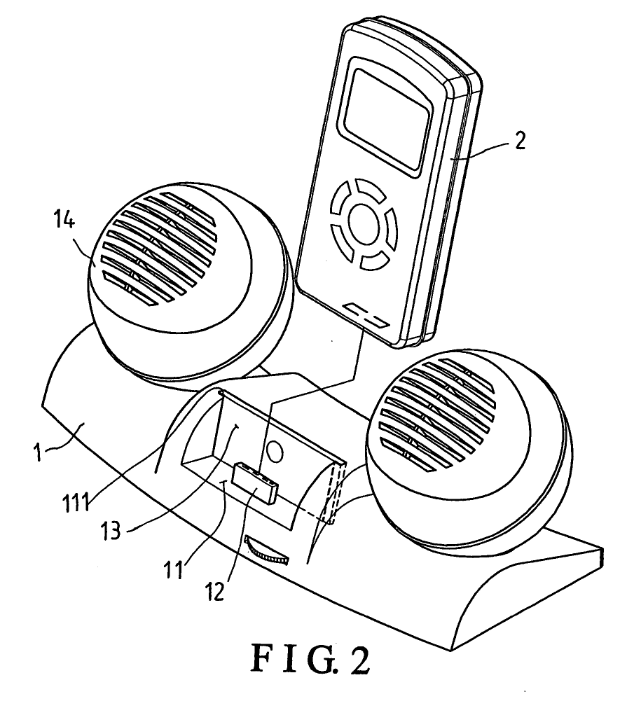

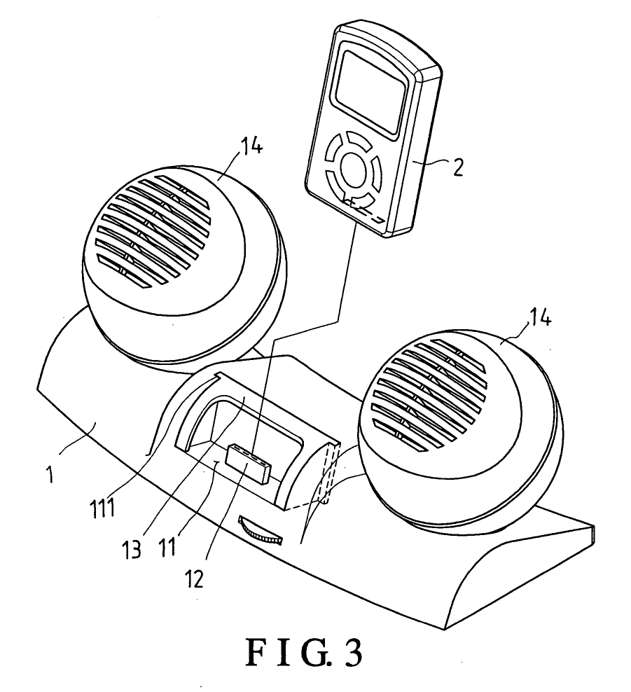

The adjusting members 13 are selectively fitted in the holding room of the holding portion 11 for changing the length and width of the same. Referring to FIG. 1 again, one of the adjusting members 13 is a substantially flat plate whose two ends can be closely fitted in the fitting trenches 111 of the holding portion 11. And, the other adjusting members 13 have a substantially flat portion whose two ends can be closely fitted in the fitting trenches 111, and two rib portions projecting from a front side of the substantially flat portion. Thus, any of players 2 with various sizes can be easily connected with the connecting terminal 12 and held steady on the support seat 1 after a suitable one of the adjusting members 13 has been fitted to the holding portion 11 with two ends being closely fitted in the fitting trenches 111, as shown in FIGS. 2 and 3. And, music can be played through the speakers 14.

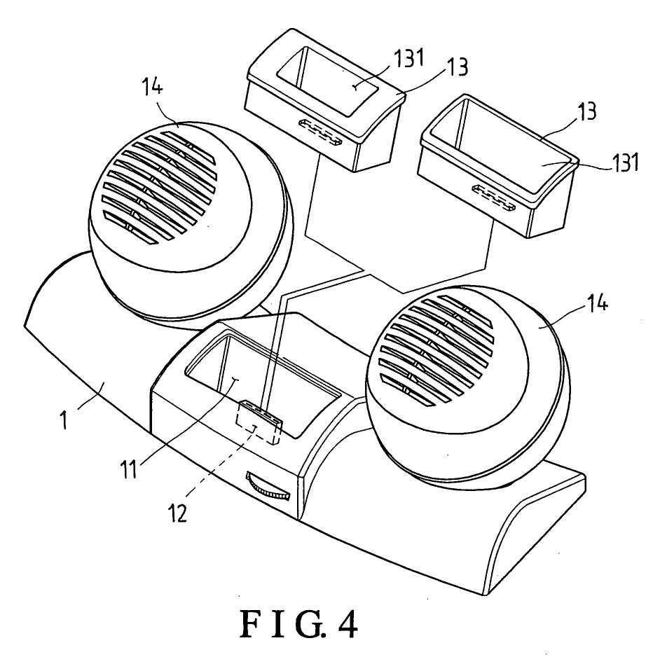

Referring to FIG. 4, in a second embodiment of the present invention, holding portion 11 of support seat 1 has a holding cavity, which extends downwards from an upper side, while connecting terminal 12 is upright in the holding cavity. And, various adjusting members 13 are provided, which can be closely fitted in the holding cavity of the holding portion 11, and which have holding spaces 131 of different sizes; thus, the adjusting members 13 can be selectively fitted in the holding portion 11 according to the size of a player that will be connected with the support seat 1. Consequently, any of players 2 with various sizes can be easily connected with the connecting terminal 12 and held steady on the support seat 1 after a suitable one of the adjusting members 13 has been inserted in the holding portion 11. And, music can be played through the speakers 14.

From the above description, it can be easily understood that with the help of the adjusting members of the support seat of the present invention, players with various sizes can be easily connected with the connecting terminal and held steady in the holding portion.

What is claimed is:

1. A support seat of an audio player, comprising
a main body; the main body having speakers at two ends thereof; the main body having a holding portion formed with a holding room; the main body having a connecting terminal connected with the holding portion in the holding room; and
a plurality of adjusting members capable of being firmly held in the holding room of the holding portion of the main body; the adjusting members having different shapes and sizes so as to cause change to dimensions of the holding room in respective ways when they are fitted in position in the holding room;
whereby music can be played through the speakers after an audio player is connected with the connecting terminal, and whereby each one of audio players with various sizes can be connected with the connecting terminal and held steady on the support seat with help of a selected one of the adjusting members.

2. The support seat of an audio player as claimed in claim 1, wherein the holding portion of the main body is formed with fitting trenches, which face and communicate with two sides of a rear end of the holding room, and one of the adjusting members is a substantially flat plate, which can be closely fitted in the fitting trenches of the holding portion at two ends thereof.

3. The support seat of an audio player as claimed in claim 1, wherein the holding portion of the main body is formed with fitting trenches, which face and communicate with two sides of a rear end of the holding room, while each of the adjusting members has a substantially flat portion, and two rib portions projecting from a front side of the substantially flat portion, which can be closely fitted in the fitting trenches at two ends thereof.

4. The support seat of an audio player as claimed in claim 1, wherein the holding room of the main body is in a shape of a cavity extending downwards from an upper side of the holding portion while each of the adjusting member has a holding space for holding an audio player therein.
